(19) United States
(12) Patent Application Publication
(10) Pub. No.: US 2011/0192441 A1
(43) Pub. Date: Aug. 11, 2011

(54) PHOTOVOLTAIC ELEMENT

(75) Inventors: Hans-Jakob STREHLER, Affoltern am Albis (CH); Werner Hillebrand Hansen, Inning (DE); Randall Jurisch, La Crescenta, CA (US); Klaus Schuer, Ingelheim (DE)

(73) Assignees: Sika Technology AG, Baar (CH); Solar Integrated Technologies GmbH, Mainz (DE)

(21) Appl. No.: 13/005,376

(22) Filed: Jan. 12, 2011

Related U.S. Application Data
(63) Continuation of application No. PCT/EP2009/059207, filed on Jul. 17, 2009.

(30) Foreign Application Priority Data
Jul. 17, 2008 (EP) 08160613.9

(51) Int. Cl. H01L 31/02

(52) U.S. Cl. 136/244; 136/256

(57) ABSTRACT

The disclosure relates to a photovoltaic element having a sealing web with at least one photovoltaic module which is mounted on one side of the sealing web and has contact points and electrical connections. The contact points of the photovoltaic module can be arranged on a side facing the sealing web, and the electrical connections can pass through the sealing web.

### RELATED APPLICATIONS

This application claims priority as a continuation application under 35 U.S.C. §120 to PCT/EP2009/059207, which was filed as an International Application on Jul. 17, 2009 designating the U.S., and which claims priority to European Application 08160613.9 filed in Europe on Jul. 17, 2008. The entire contents of these applications are hereby incorporated by reference in their entireties.

### FIELD

The disclosure relates to photovoltaic elements.

### BACKGROUND INFORMATION

Photovoltaic elements are known in general and have been mostly used for application to a roof surface. In this connection, several photovoltaic elements with their sealing webs are bonded next to one another so that the bonded photovoltaic elements provide a power generation function and, at the same time, perform the function of a roof seal.

Fundamentally, single-layer and multi-layer photovoltaic systems can be distinguished. For a two-layer system, the upper layer performs the photovoltaic function, while the lower layer performs the sealing function. The layers are applied separately, the lower layer not being pierced for the electrical connections. Cabling can take place after completion of the sealing activities so that there is no danger of damaging the contact points when walking on the roof and so that expensive protection of contact points by mechanical covers is unnecessary. The sealing situation is very reliable, but this version can be relatively costly because two plastic sealing webs are used and applied.

The single-layer systems are additionally distinguished according to the type of cabling:

On the one hand, in a single-layer system, the connection of the photovoltaic modules to the cabling takes place from underneath with the sealing web being pierced. The cabling itself is laid in the heat insulation layer of the roof. In this connection of the roof layer package, the insulation+vapor barrier+support structure, is pierced once per four photovoltaic modules and the sealing plane is pierced once every 2-3 m². An advantage is a low danger of damage of the contact points when walking on the roof, and the contact points need not be protected with mechanical covers. Furthermore, only one sealing web layer is used. However, a frequent piercing of the sealing plane is performed in the flat roof region. Piercing approaches can be especially risky in application with respect to leaks, and can be expensive because they impose special demands on the technical approach and the professional skill of the installer. Cabling and sealing efforts are carried out with one another. This takes longer and there are several individuals on the roof; this leads to greater risks in working. The risk of leaks thus also rises.

On the other hand, there is also a single-layer system in which the connection of the photovoltaic elements to the cabling takes place overhead the photovoltaic module (that is, the top), and cabling also takes place on top of the flat roof. An advantage is that piercing of the sealing plane is avoided, cabling after completion of the sealing efforts is possible, and only one layer of sealing web is used. However, there is the great danger of damage to the contact points when walking on the roof, or use of expensive protection of the contact sites with mechanical covers.

### SUMMARY

A photovoltaic element is disclosed comprising: a sealing web; and at least one photovoltaic module which is attached on one side of the sealing web and which has contact points and means of electrical connection, wherein the contact points of the photovoltaic module are located on a side of the photovoltaic module facing the sealing web, and the means of electrical connection pierce the sealing web.

### BRIEF DESCRIPTION OF THE DRAWINGS

Exemplary embodiments are detailed below using the drawings, wherein only features which are necessary for understanding of the disclosure are shown. In the drawings:

FIG. 1 shows a cross section through an exemplary photovoltaic element in a region of the contact points;

FIG. 2 shows a cross section through a photovoltaic element with a cover web in the region of the contact points;

FIG. 3 shows an oblique view of a partially unrolled photovoltaic element;

FIG. 4 shows an unrolled photovoltaic element with four photovoltaic modules;

FIG. 5 shows a cross section through one photovoltaic element in the region of the contact points;

FIG. 6 shows a cross section through a photovoltaic element with a cover web in the region of the contact points;

FIG. 7 shows a cross section through a photovoltaic element with a nipple for an inner region between a sealing web and the cover web; and

FIG. 8 shows a cross section through a photovoltaic element with a nipple similar to FIG. 7, but with guidance of an electrical connection through the nipple for testing integrity.

### DETAILED DESCRIPTION

A photovoltaic element is disclosed which for the most part exploits advantages of single-layer systems and two-layer systems and avoids their drawbacks.

Contact points of a photovoltaic module are located on a side facing a sealing web and means of electrical connection pierce the sealing web.

An exemplary development of the photovoltaic element calls for the means of electrical connection to the contact points to pierce the sealing web twice. In the case of several photovoltaic modules, an exemplary version of the photovoltaic element calls for the means of electrical connection of the contact points to pierce the sealing web twice between two contact points. For example, for the means of electrical connection can pierce the sealing web twice following the contact point on the photovoltaic module.

Provisions can be made for very reliable sealing by an additional covering web being applied along the piercing points in a region of the piercing points of the sealing web on a bottom of the sealing web (e.g., bonded and/or cemented on) and can, for example, comprise (e.g., consist of) plastic, such as plastic of the same material as the sealing web itself. The additional covering web in its longitudinal direction can run along the piercing points.

One exemplary reliable version with respect to sealing reliability is achieved when there is a molded piece in the region of the covering web; this piece forms an air-permeable connection to a cavity which is formed by the cover web and the sealing web. In this way the tightness of the system can be demonstrated using a vacuum test.

The molded piece can be connected to the sealing web or even on the bottom of the sealing web (e.g., bonded and/or cemented on). If this molded piece is used, it can also be additionally used to route at least one electrical connection or all electrical connections through this molded piece to the outside. In this way, possible additional leak sites can be avoided.

Another exemplary embodiment calls for the means of electrical connection to have plug-and-socket connections so that simple cabling is possible.

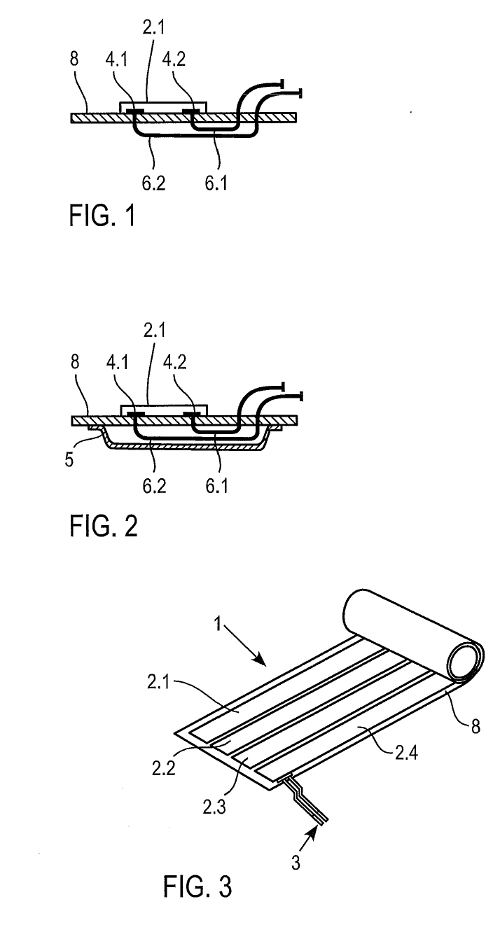

FIG. 1 shows an exemplary photovoltaic element 1 with a photovoltaic module 2.1 which is attached on one side of the sealing web. The contact points 4.1 and 4.2 of the photovoltaic module 2.1 are located on the side facing the sealing web 8 and a means of electrical connection 6.1 or 6.2 pierce the sealing web 8. The contact sites 4.1, 4.2 each route out the positive or negative polarity of the respective photovoltaic module. The means of electrical connection 6.1 or 6.2 which are attached to the respective contact point 4.1, 4.2 can be used to connect the photovoltaic element 1 in series or parallel to other photovoltaic elements. Of course the means of electrical connection 6.1 or 6.2 which are attached to the contact points 4.1, 4.2 can also pierce the sealing web jointly at the same location. In the case of a photovoltaic element 1 with several photovoltaic modules which are attached on one side of the sealing web, the photovoltaic modules can be connected in series or parallel among one another. In the case of a serial connection, a higher voltage can result, while in a parallel connection there can be a higher current intensity.

FIG. 2 shows the photovoltaic element 1 from FIG. 1, with a cover web 5 applied on the bottom of the sealing web 8 (e.g., cemented and/or bonded) to reliably ensure permanent sealing of rooves using the photovoltaic elements 1.

FIG. 3 shows an exemplary photovoltaic element 1 in a partially rolled state, having of a sealing web 8, on which four photovoltaic modules 2.1 to 2.4 are fixed and which has a common plug-and-socket connection 3 for an external current terminal.

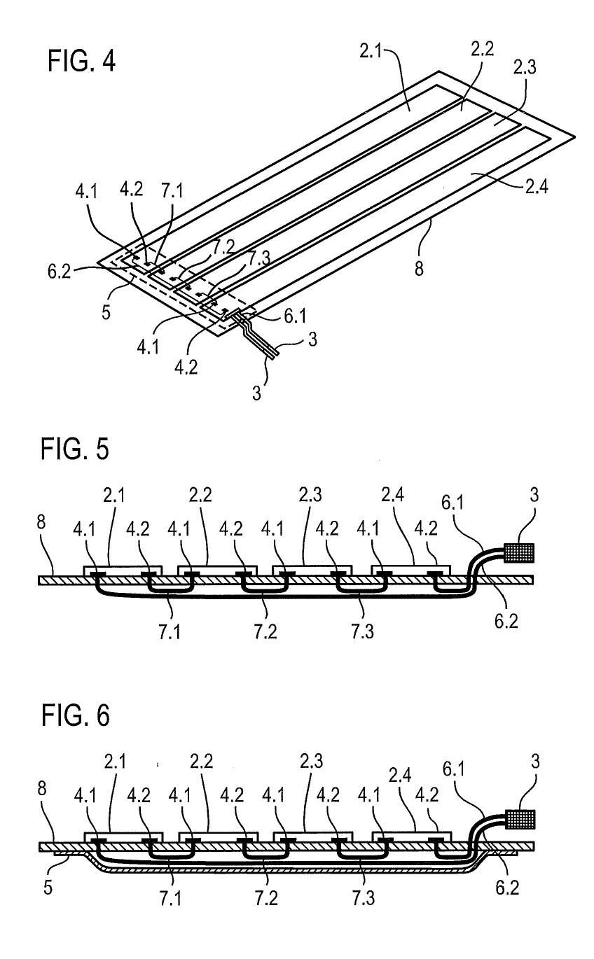

FIG. 4 shows an exemplary photovoltaic element from FIG. 3 in an unrolled state. In the left region on the individual photovoltaic modules 2.1 to 2.4, contact points 4.1, 4.2 are shown which each route out the positive or negative polarity of the respective photovoltaic module and on which the means of electrical connection 6.1 or 6.2 are attached to the contact points. These contact points 4.1, 4.2 are attached on the bottom of the photovoltaic modules 2.1 to 2.4 so that they point in the direction of the underlying sealing web 8. At these contact points 4.1 and 4.2 on the one hand means of electrical connection 7.1 to 7.3 make contact between the individual photovoltaic modules 2.1 to 2.4 and pierce the sealing web 8 at the piercing points immediately following their respective contact points, run on the bottom of the sealing web 8, and again pierce the sealing web 8 over one piercing point toward the oppositely polarized contact point of the overlying photovoltaic module. At an end of a serial connection row of the photovoltaic modules 2.1 to 2.4, one means of electrical connection 6.1 or 6.2 at a time can be connected to the contact point, and run directly behind the contact point and onto the side on which the entire electrical connection of the photovoltaic element 1 is located, where they again pierce the sealing web 8 from underneath. Of course it is also possible to connect the photovoltaic modules 2.1 to 2.4 in parallel among one another.

In a region of the piercing points of the means of electrical connection 6.1, 6.2 and means of electrical connection 7.1 to 7.3 which run there, on the bottom of the sealing web there is again a cover web 5 which surrounds the entire region and covers it in, for example, a watertight manner. The cover web 5 is connected to the sealing web 8 (e.g., cemented and/or bonded), so that a reliable sealing situation is present.

FIG. 5 again shows the region of the piercing points or the contact points 4.1 and 4.2 in cross section.

FIG. 6 shows the photovoltaic element 1 from FIG. 5, with the cover web 5 being applied on the bottom of the sealing web 8 (e.g., cemented and/or bonded), and in this way reliably ensuring permanent sealing of rooves using the photovoltaic elements 1.

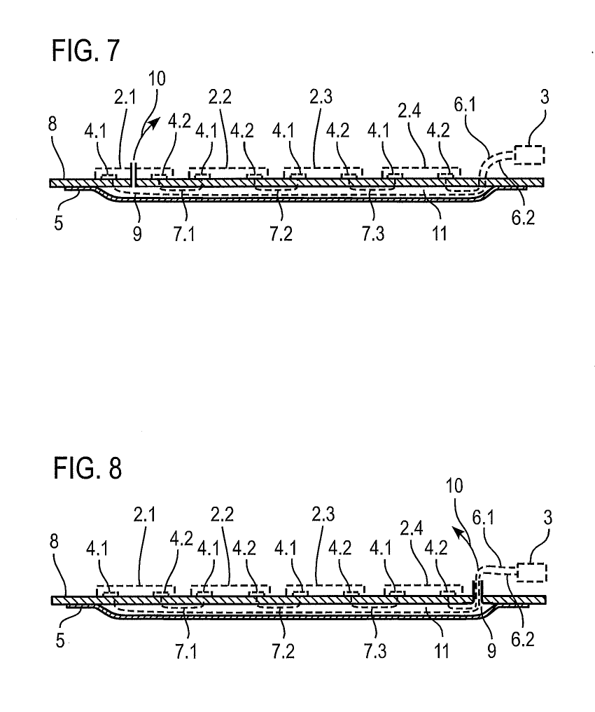

In an exemplary embodiment, a nipple 9 can be attached to the sealing web 8 in a region of the cavity which is formed by the sealing web 8 and the cover web 5 which is applied underneath (e.g., cemented and/or bonded) as shown in FIG. 7. A vacuum can be produced in the intermediate space 11 between the sealing web 8 and the cover web 5 by exhausting air through this nipple which can be made, for example, flexible and rigid and can be bonded to the sealing web 8 as a molded piece. In this way the tightness can be checked according to an optionally measurable pressure drop so that tightness of the entire system of the photovoltaic element 1 can be ensured with high reliability. Moreover this nipple can also be used to route the means of electrical connection 6.1 or 6.2 to the outside, as is shown in FIG. 8. This measure can prevent possible leaks due to other openings. To check tightness, an air-insulated termination can be used which makes it possible to briefly accommodate the plug 3 at the same time, or the connections to the plug can be prepared later so that only the means of electrical connection 6.1 and 6.2 are housed in the air-insulated termination.

The aforementioned features of the disclosure can be used not only in the respectively indicated combination, but also in other combinations or alone without departing from the framework of the disclosure.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE NUMBER LIST

1 photovoltaic element
2.1-2.4 photovoltaic modules
3 plug-and-socket connection
4.1, 4.2 contact points
5 cover web
6.1, 6.2 means of electrical connection
7.1-7.3 means of electrical connection
8 sealing web
9 molded piece/nipple
10 air
11 intermediate space

What is claimed is:

1. Photovoltaic element comprising:
a sealing web; and
at least one photovoltaic module which is attached on one side of the sealing web and which has contact points and means of electrical connection, wherein the contact points of the photovoltaic module are located on a side of the photovoltaic module facing the sealing web, and the means of electrical connection pierce the sealing web.

2. Photovoltaic element as claimed in claim 1, wherein the means of electrical connection pierce the sealing web twice.

3. Photovoltaic element as claimed in claim 1, comprising:
at least two photovoltaic modules attached on one side of the sealing web and including means of electrical connection.

4. Photovoltaic element as claimed in claim 3, wherein the means of electrical connection electrically connect the contact points in series with one another.

5. Photovoltaic element as claimed in claim 1, wherein the sealing web is a flexible, sealing web produced from plastic.

6. Photovoltaic element as claimed in claim 1, wherein in a region of piercing points of the sealing web on a bottom of the sealing web, a cover web is applied along piercing points.

7. Photovoltaic element as claimed in claim 6, wherein the cover web is made of plastic.

8. Photovoltaic element as claimed in claim 6, wherein the cover web consists of a same material as the sealing web.

9. Photovoltaic element as claimed in claim 6, wherein the cover web in a lengthwise direction runs along the piercing points.

10. Photovoltaic element as claimed in claim 6, wherein in a region of the cover web there is a molded piece which forms an air-permeable connection to a cavity which is formed by the cover web and the sealing web.

11. Photovoltaic element as claimed in claim 10, wherein the molded piece is connected to the sealing web.

12. Photovoltaic element as claimed in claim 10, wherein the molded piece is connected on the bottom of the sealing web.

13. Photovoltaic element as claimed in claim 10, wherein at least a portion of the means of electrical connection is routed outside the photovoltaic element through the molded piece.

14. Photovoltaic element as claimed in claim 1, wherein the means of electrical connection have plug-and-socket connections.

15. Photovoltaic element as claimed in claim 1, wherein the photovoltaic module comprises:
at least two contact points, one for each of two different polarities.

16. Photovoltaic element as claimed in claim 1, wherein the photovoltaic module is flexible.

17. Photovoltaic element as claimed in claim 5, wherein the sealing web is a liquid tight, sealing web produced from plastic.

18. Photovoltaic element as claimed in claim 2, wherein in a region of piercing points of the sealing web on a bottom of the sealing web, a cover web is applied along piercing points.

19. Photovoltaic element as claimed in claim 18, wherein in a region of the cover web there is a molded piece which forms an air-permeable connection to a cavity which is formed by the cover web and the sealing web.

20. Photovoltaic element as claimed in claim 19, wherein the photovoltaic module comprises:
at least two contact points, one for each of two different polarities.
